(19) United States
(12) Patent Application Publication
(10) Pub. No.: US 2007/0210393 A1
(43) Pub. Date: Sep. 13, 2007

(54) Lithographic Method Products Obtained And Use Of Said Method

(76) Inventors: Jean-Luc Rehspringer, Lingolsheim (FR); Laurent Bedel, Illkirch-Graffenstaden (FR)

Correspondence Address: YOUNG & THOMPSON, 745 SOUTH 23RD STREET, 2ND FLOOR, ARLINGTON, VA, 22202, US

(21) Appl. No.: 11/547,774

(22) PCT Filed: Apr. 8, 2004
(86) PCT No.: PCT/FR04/00876

§ 371 Date: Dec. 4, 2006

(51) Int. Cl. H01L 21/02; G03F 7/004; H01L 29/66

(52) U.S. Cl. 257/415; 438/57; 257/E31.001

(57) ABSTRACT

A lithographic method, products obtained thereby and use of the method, in particular, in the production of micro- or nano-metric products or objects. The method includes the steps of deposition of a film of an organometallic solution of a substrate, containing at least one metal ion as precursor(s) for marking the substrate, local exposure, according to the required pattern, of the obtained film, via at least one focussed energetic beam, with an energy density sufficient to at least locally dry the film, dissolution of the non-exposed zone, the at least dried zones remaining on the substrate, optionally subjecting the obtained product to a thermal treatment and, where necessary, repetition of certain steps, with optional change to the organometallic solution, until the required final product is obtained.

This invention relates to the field of physical chemistry and more particularly to that of the processes for treatment of surfaces. It has as its object an improved process of lithography as well as the products that are obtained for the implementation of said process and is particularly useful in the production of micrometric or nanometric products or objects. This invention makes possible in particular a simplified production of multilayer electronic structures, in particular multilayer mesostructures and nanostructures for optical and electronic applications and in particular printed circuits or field-effect transistors commonly designated under the English name “MOS-FET transistor.”

Currently, the production of the industrial components of the type mentioned above requires a tracing of active and passive components that employ masks produced in the form of a polymer layer (typically of methyl polymethacrylate: PMMA). These ;! masks are produced on the substrate by local depolymerization of said uniform PMMA layer by a light source through a metal mask, namely plates pierced at spots to undergo irradiation. Now, the critical irradiation stage generally takes place by an ultraviolet light flow that depolymerizes an underlying polymer at locations not covered by said masks. The degraded polymer is then eliminated by washing of the substrate to make the pattern or the desired structure appear. This process is then repeated until the desired pattern or final multilayer product is obtained.

The wavelength of the irradiation sources currently used, however, does not in general make it possible to produce objects, for example electronic components, that are less than 200 nm in size.

In addition, the large number of stages necessary in the processes currently used in the industry as well as the use of noxious and costly chemical products makes the latter long, complicated and expensive, while multiplying the risks of obtaining products of insufficient quality if at least one of the stages is carried out in an unsuitable manner.

The process according to the invention makes it possible to produce in a simplified way nanometric objects that may or may not have magnetic oxide, metallic nanometric objects or objects that are made of certain semi-conductors. It dispenses with tedious and delicate stages of masking and the production of polymer imprints, and it also makes possible the formation of nanometric conducting strips that are preferably made of copper and/or gold and the formation of certain semi-conductors.

For this purpose, this invention has as its object a lithography process, characterized in that it comprises essentially the stages consisting in:
a) Depositing, on a substrate, a film of a metallo-organic solution that contains at least one metal ion as (a) precursor(s) intended to mark said substrate,
b) Locally exposing, according to the desired pattern, the film that is obtained in stage a) to at least one focused energy beam that has an adequate energy density for at least drying said precursor film locally,
c) Dissolving the zones that are not exposed in stage b) with the assistance of a solvent of the metallo-organic solution deposited in stage a), whereby the zones that are at least dried remain on said substrate,
d) If necessary, subjecting the product that is obtained in the preceding stage to a heat treatment for the purpose of obtaining, at the exposed zones, magnetic oxide, metal, the semi-conductor or neutral oxide or mixtures thereof obtained from said metallo-organic solution, and
e) If necessary, repeating stages a)-d), optionally by changing the metallo-organic solution, until the desired final pattern or final multilayer structure is obtained.

It also has as its object a device that is manufactured in multiple layers, characterized in that it comprises at least one structure or a pattern obtained by the implementation of the process according to the invention.

Finally, it also has as its object the use of the process according to the invention in the production of electronic components, in particular transistors, and more preferably field-effect transistors as in the production of printed circuits.

As explained below, the process according to the invention avoids the cumbersome stages that usually resort to physical methods of metal deposits by sublimation under ultrahigh vacuum (as known under the designations of “MBE” and “sputtering”) with the successive and tedious stages of masking for the formation of nanometric objects such as in particular the above-mentioned “MOS FET”-type transistors (metal oxide semi-conductor field-effect transistor).

According to the process in accordance with this invention, the production of nanometric objects is done with the assistance of a scanning electronic microscope connected to a computer, making it possible to monitor the position of the energy beam (for example, an electron beam) with high precision. A thin layer of precursor solution is deposited on the surface of a substrate sample to be treated, and the electron beam dries and/or transforms said precursor in substance before being deposited. A combination of solvents later makes it possible to dissolve the non-exposed regions.

Once the desired patterns are lithographed, it is no longer necessary to deposit, by evaporation, a metal on the surface of said sample, the latter being obtained by reaction with the electronic beam and optionally stabilized by a reducing heat treatment.

The use of the electron beam comprises several advantages relative to the standard lithography techniques using optical means. First, the wavelength of the electrons is much smaller than that of the ultraviolet. This makes it possible to obtain a significantly superior resolution. Second, the use of a computer-controlled scanning electronic microscope means that it is not necessary to make complex photolithographic masks to measure, therefore costly, as is the case, for example, for ultraviolet lithography.

Within the framework of the process according to the invention, in reality direct writing on the samples or substrates of interest is initiated, and the technology thus offers much flexibility for the rapid modification of written patterns.

The invention will be better understood thanks to the description below, which relates to a preferred embodiment, given by way of nonlimiting example and explained with reference to the attached schematic drawings, in which:

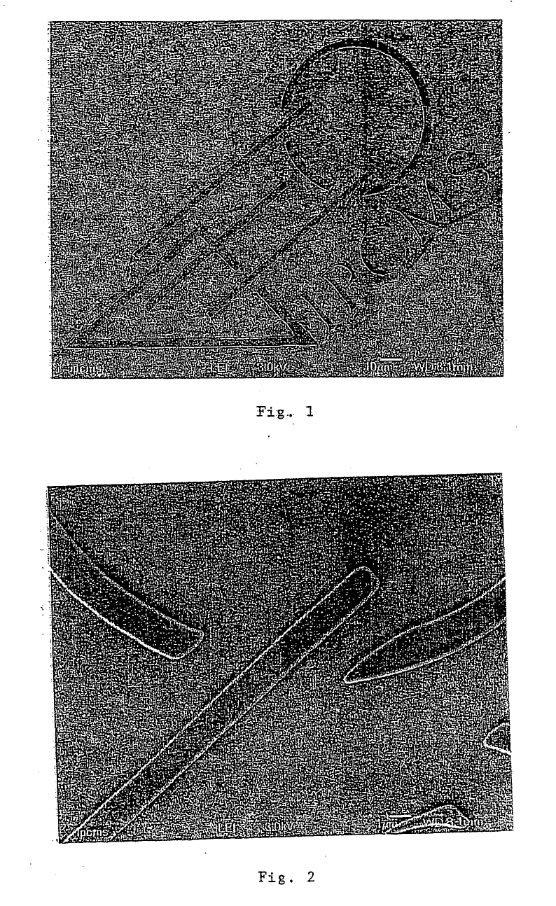

FIG. 1 shows the photograph of a first sample object made of Fe₂O₃ on silicon 100 thanks to the implementation of the process according to the invention,

FIG. 2 shows an enlargement of a portion of the photograph of FIG. 1,

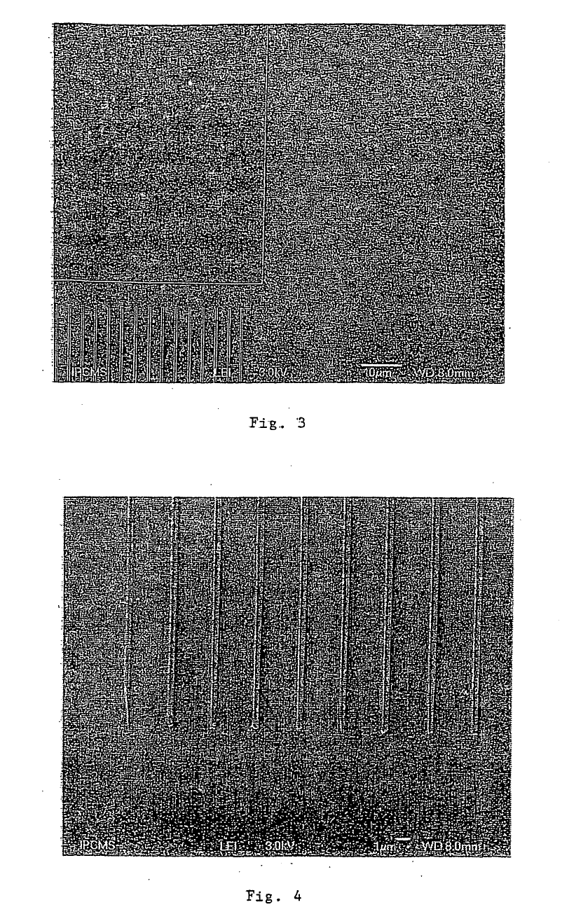

FIG. 3 shows the photograph of a second sample object made of CoFe₂O₄ on silicon 100 thanks to the implementation of the process according to the invention,

FIG. 4 shows an enlargement of a portion of the photograph of FIG. 3, and

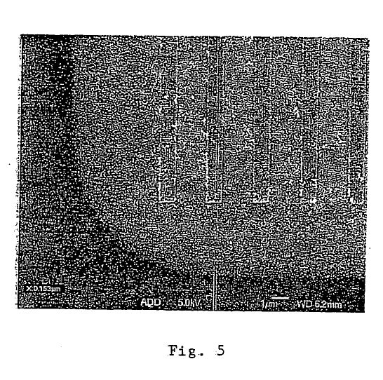

FIG. 5 shows the photograph of a third sample object made of metal (gold) thanks to the implementation of the process according to the invention.

According to this invention, the lithography process is characterized in that it comprises essentially the stages that consist in:
a) Depositing, on a substrate, a film of a metallo-organic solution that contains at least one metal ion as (a) precursor(s) intended to mark said substrate,
b) Locally exposing, according to the desired pattern, the film that is obtained in stage a) to at least one focused energy beam that has an adequate energy density for at least drying said precursor film locally,
c) Dissolving the zones that are not exposed in stage b) with the assistance of a solvent of the metallo-organic solution deposited in stage a), whereby the zones that are at least dried remain on said substrate,
d) If necessary, subjecting the product that is obtained in the preceding stage to a heat treatment for the purpose of obtaining, at the exposed zones, magnetic oxide, metal, the semi-conductor or neutral oxide or mixtures thereof obtained from said metallo-organic solution, and
e) If necessary, repeating stages a)-d), optionally by changing the metallo-organic solution, until the desired final pattern or final multilayer structure is obtained.

Thus, a metallo-organic solution is deposited, preferably by “spin-coating” (rotary deposition) on a flat substrate, in particular of silicon or a vitreous material. Introduced into a device that can provide an electron beam or an ion beam (collimated or not), the metallo-organic coating or layer is then exposed to said beam. In the exposed zones, said coating is degraded and becomes insoluble in the common solvents (alcohol, acetone, water, etc.). It thus is possible to trace submicronic objects (strips, contacts, wires, networks, etc. . . . ) and even nanometric objects according to the size and intensity of the beam.

The marked substrate that exits from the irradiation equipment is then quenched in a conventional way in a suitable solvent. The non-irradiated portions are then dissolved, thus revealing the imprinted submicronic or nanometric objects. Said substrate can then undergo a new overall coating to deposit another layer of another metallo-organic or quite simply to be heat-treated to form in the non-dissolved zones: a magnetic oxide (for example, Fe₂O₃, CoFe₂O₄, . . . ), a metal (Cu, Co, . . . ), a semi-conductor (CdS, CdSe, ZnS, ZnSe, . . . ), or a neutral oxide (TiO₂, Al₂O₃, ZnO, . . . ) according to the electronic device that it is desired to form or to complete.

The device that is used for the production of the microstructures or nanostructures as well as for the observation thereof is a scanning electronic microscope as known, for example, under the reference JEOL-JMS 6300 of the JEOL manufacturer.

Such a scanning electronic microscope (MEB) has a maximum magnification of 300,000 times and a maximum resolution on the order of 5 nm. The maximum energy of electrons produced by this MEB is on the order of 30 keV. For the production of the desired nanometric objects, said MEB is connected to a conventional personal computer that monitors the position of the electron beam according to a process that is known in the art and that does not need to be explained in more detail here. The computer also monitors a beam interceptor that is located above the sample. The latter makes it possible to carry out a point-by-point exposure of the sample without exposing the resin at undesirable locations.

According to a characteristic of the process according to the invention, the substrate is silicon or laminated mica.

Preferably, the surface of the substrate is that of a monocrystal.

According to another characteristic, the substrate is a ceramic, in particular a glass.

According to another characteristic, the substrate is a metal or a metal alloy.

Advantageously, the metallo-organic solution contains at least one organic salt from at least one metal that is selected from the group that is formed by: Cd, Ti, Al, Si, Fe, Co, Ni, Mn, Cr, Zn, Cu, Ca, Ba, Sr, Y, Zr, Sn, Ag, La, Hf, Ta, Pb, Bi, In, Ce, Pr, Nd, Sm, Eu, Gd, Yb, Er, Tb and U.

Preferably, the metallo-organic salt or salts are selected from among the group that is formed by: the carboxylates, the propionates, the butyrates, the pentanoates, the metal methylbutyrates, or a mixture of the latter.

According to another advantageous embodiment, the metallo-organic solution also comprises at least one mineral salt of at least one noble metal that is selected from the group that is formed by Au, Ag and Pt, preferably AuCl₃, AgNO₃, or PtCl₅, or a mixture of the latter.

According to this invention, the energy beam is an electron beam or an ion beam.

Advantageously, the energy density of the energy beam is between 100 and 100,000 A.s.m².

According to a variant, the energy density of the energy beam is adequate for modifying, in the exposed zones, the chemical nature of the metal or metals contained in the metallo-organic solution.

Advantageously, it is provided that the metallo-organic solution that contains at least Cd or Zn also contains a compound that can release sulfide ions at the time of the exposure of stage b) and/or during the heat treatment of stage d).

The desired pattern (insulating deposit, magnetic, line for future conducting strips or power lead-ins . . . ) is prepared on specific DAO software that is also known in the art and then is interpreted in terms of point-by-point movement orders of the electronic beam. The electron beam or ion beam dries and/or transforms the precursor that is used as indicated above.

Prior to said exposure, said precursors will have been spread over the samples with a device that makes it possible to deposit the latter uniformly on the substrate, for example, with a device commonly called a “spinner” in the technical jargon in question. Usually, a drop of metallo-organic solution is thus deposited on the sample (or substrate) that is later rotated at the rate of a speed on the order of 5000 rpm for 60 seconds.

Once the exposure is carried out, a solvent or a combination of solvents is used as a developer, i.e., as a substance that makes it possible to eliminate only the molecules that have not been exposed.

In concrete terms, the process that is implemented therefore reveals, after washing, for a longitudinal irradiation, a line in relief, or, for an irradiation on a circular surface, a disk in relief.

In a traditional production process, a metal layer is to be evaporated over the entire surface of the developed sample. The metal can be evaporated in two ways: by heat or by an electron gun. In the first case, a small amount of metal is put into a tungsten crucible and is heated above the boiling point, in a vacuum, in the presence of the sample or the substrate. In the second case, the metal is heated by an electron gun. The most commonly used metals for the nano-production are NiCr (eutectic alloy of nickel and chromium) as well as AuPd (eutectic alloy of gold and palladium) and are evaporated thermally. The electron gun evaporator is generally used for evaporation of multiple layers of different metals, as necessary for the ohmic contacts or the Schottky contacts. These stages, which are often difficult to implement and which represent a significant cost as well as an additional potential source of defects, are avoided in the process according to the invention.

In a standard production process, the last stage consists in detaching the metal that is deposited on the resin from the surface of the sample. Thus, only the regions where the resin was removed in advance remain covered by metal. This process, commonly called “lift-off,” is done by allowing the sample to be quenched in a mixture of acetone and MEK (methyl ethyl ketone), strong solvents that work so as to dissolve all of the resin, whatever its molecular weight. After a certain time, the solvents are stirred such that the metal that is on the resin is removed.

Two mixtures are widely used here as developers, namely, on the one hand, a mixture of isopropyl alcohol and water (IPA:H₂O), and, on the other hand, a mixture of isopropyl alcohol and methyl isobutyl ketone (IPA:MIBK). Of course, the polymers are dissolved in different types of solvents and in different proportions as required. The most used solvents for the resins are methyl isobutyl ketone (MIBK), orthoxylene and chlorobenzene. The chlorobenzene is the strongest of these solvents and is used for the highest PMMA concentrations (for example on the order of 15%). For the lower concentrations, typically between 2.5% to 6% by weight of PMMA, the orthoxylene is perfectly suitable.

Thanks to the process according to the invention, no organic polymer is therefore required, nor, consequently, any costly, noxious, and polluting solvent for the traditional “lift-off” stage referred to above, unnecessary in the process according to this invention.

The process according to the invention is similar to a direct lithography technique in that in addition to the fact of requiring only a single imprinting stage (saving of time during the imprinting and during the quality monitoring of the latter), it does not use any masking.

As well as the substantial lowering of the final cost of a component that is produced by the process according to the invention, the very great diversity of the materials that can be produced (magnetic oxides, semi-conductors, conducting strips or insulating strips, . . . ) is another important advantage. Thus, by way of example, metal objects can now be obtained without resorting to the cumbersome stage of metal vaporization.

The process according to the invention becomes all the more flexible as the chemical nature of the substrate virtually does not condition the successful outcome of the lithography. It is possible to lithograph objects on almost any substrate, which may or may not be smooth, in particular on glass.

By way of pure indication, the process according to this invention can be used in the field of microelectronics, in the catalysis of nano-tubes oriented for plasma screens, for biochips, for very high density magnetic recording, for the production of logic gates, GMR memories, UV-visible detectors, for the safety marking of components, for the production of micromachines, . . . .

The process according to the invention will now be explained in more detail with the assistance of the following examples provided by way of nonlimiting example.

### EXAMPLE 1

### Production of Iron Oxide Contacts

An iron propionate solution is prepared by dissolution of iron propionate in a suitable solution such as ethanol, propanol, butanol or acetone. To obtain an oxide layer that is typically on the order of 0.2 μm, a solution will be prepared with 1 mol per liter of iron propionate.

The substrate, typically of polished monocrystalline silicon 100 at lambda over 10 and previously cleaned by means that are well known to one skilled in the art, is deposited on the spinner, a device that is conventionally used in microelectronics and that makes it possible to deposit layers by centrifuging. Several drops of the above-mentioned iron propionate solution are deposited on the substrate so that the latter is typically covered by solution without overflowing, then the substrate is rotated at a speed of between about 1000 and 5000 rpm for, for example, 30 seconds. The deposited liquid spreads out to form a thin film of several tenths of a micrometer (0.3 to 0.6 μm).

The thus prepared substrate is carefully drawn off from the device and deposited in a box protected from dust (primarily if this operation does not take place in a clean room) and transferred into an electrolithography device.

First, the diagrams of nano-objects that it is desired to produce will have been designed and programmed in a conventional manner on the DAO software (of the type known under the name “autocad” or compatible) and transcribed in corresponding movements of the electron beam in the device. The prepared substrate then undergoes the specific irradiations as provided with an ion beam that is typically on the order of 1000 A.s.m.⁻². The irradiation that makes possible the formation of a network of 100 parallel wires of several 200 nm of thickness and one micrometer of width separated by one micrometer lasts for approximately several minutes (from 0.1 to 3 minutes based on the dose and the thickness of the sample). The substrate is drawn off from the microscope and is quenched in a solvent, typically ethanol, for 30 seconds. Then, it is drawn off and dried.

One observation by scanning electronic microscope shows that the irradiated zone is maintained. To obtain the corresponding oxide, the above-mentioned sample will be subjected to a heat treatment between 300° C. and 500° C. for an adequate time. This will then result in gamma-iron oxide with a spinel structure.

The thus obtained substrate is consequently reusable for the application of another deposit, if necessary.

FIGS. 1 and 2 show photographs of a sample structure made of Fe₂O₃ on Si 100 thanks to the implementation of the process according to the invention.

### EXAMPLE 2

### Production of Spinel Contacts of Iron and Cobalt

The production procedure is similar to the preceding procedure, only the composition of the solution being modified. The dissolution of iron and cobalt propionates will be initiated in the proportions of two iron atoms per one cobalt atom. The final heat treatment will be conducted at a temperature of 700° C. to 800° C. and in an adequate period for obtaining the desired chemical compound.

This production type can be applied to obtaining binary oxides of spinel type, perovskite, garnet or hexaferrite as well, which can exhibit an advantage in microelectronics or in quantum electronics. There can be prepared, for example, ZnFe₂O₄, CuFe₂O₄, BaFe₁₂O₁₉, Y₃Fe₅O₁₂ garnet, LaFeO₃, . . . .

FIGS. 3 and 4 show photographs of a sample object made of CoFe₂O₄ on Si 100 thanks to the implementation of the process according to the invention.

### EXAMPLE 3

### Production of Nanometric Metal Contacts or Strips Made of Cobalt, Iron or Copper

The production procedure is similar to the one of Example 1, only the composition of the solution being modified. The dissolution of cobalt propionate, iron or copper will be initiated.

At the end, the heat treatment, oxidizing under air, will be conducted at 400° C. for the cobalt, then a reduction under hydrogen in which the reducing mixture will typically be brought to a temperature of 400-500° C. for obtaining metal. For iron or copper, the annealing and/or reduction temperatures will be adapted to the specific case of each metal.

FIG. 5 shows a photograph of a sample structure that is made of metallic gold thanks to the implementation of the process according to the invention.

### EXAMPLE 4

### Preparation of Nanometric Objects of Semi-Conducting Cadmium Sulfide

The production procedure is similar to the one of Example 1, only the composition of the solution being modified. The dissolution of cadmium carboxylate will be initiated, and excess compound that can release sulfide ions during its decomposition, typically thiourea, will be added to this solution. During the irradiation stage, the thiourea breaks down, releasing the sulfide ions that combine immediately into cadmium to form the desired semi-conducting CdS.

### EXAMPLE 5

### Preparation of Nanometric Objects of Insulation such as TiO₂, Al₂O₃ or SiO₂

The production procedure is similar to the one of Case 1, only the composition of the solution being modified. The dissolution of the carboxylate of titanium, aluminum or silicon will be initiated. At the end of the forming of said structures, the heat treatment, oxidizing under air, will be conducted at about 600° C.

The process according to the invention makes it possible to produce structures on the order of about 10 nanometers. By way of indication, it becomes possible, for example, to produce in a reproducible manner a metal line of about 45 nm of width, a point with a width of less than 50 nm, as well as spacing between two metallic structures of about 15 nm.

The process according to the invention is therefore advanced technology for the production of electronic components in the sense that it makes it possible to significantly decrease the value of 190 nm that is usually encountered for the gate width of a transistor to a gate width of between 2 and 100 nm.

This can be carried out thanks to the possibility, in transistors obtained by the process according to the invention, of being able to increase concurrently the constant c of the dielectric used that can go from a value of about 10 units S. I. for the actual processes to a value on the order of 100 to 3000 units S. I. for the process according to the invention according to the new insulation that can now be used.

This invention also has as its object a device that is produced in multiple layers, characterized in that it comprises at least one structure or one pattern obtained by the implementation of the process according to the invention.

Furthermore, this invention also has as its object the use of the process according to the invention in the production of electronic components, in particular transistors, and more preferably field-effect transistors as well as in the production of printed circuits.

In the case of the production of a transistor, for example, it will be suitable to adapt the process according to the invention in particular by providing the usual stages of silicon doping (implantation by phosphorus ions for the creation of doped zones) by the standard methods that are known in the art and can be easily transferred by one skilled in the art with this process.

Of course, the invention is not limited to the embodiment described and shown in the attached drawings. Modifications remain possible, in particular from the standpoint of the constitution of the various elements or by substitution of equivalent techniques, without thereby going outside the field of protection of the invention.

1. Process of lithography, characterized in that it comprises essentially the stages consisting in:
a) Depositing, on a substrate, a film of a metallo-organic solution that contains at least one metal ion as (a) precursor(s) intended to mark said substrate,
b) Locally exposing, according to the desired pattern, the film that is obtained in stage a) to at least one focused energy beam that has an adequate energy density for at least drying said precursor film locally,
c) Dissolving the zones that are not exposed in stage b) with the assistance of a solvent of the metallo-organic solution deposited in stage a), whereby the zones that are at least dried remain on said substrate,
d) If necessary, subjecting the product that is obtained in the preceding stage to a heat treatment for the purpose of obtaining, at the exposed zones, magnetic oxide, metal, the semi-conductor or neutral oxide or mixtures thereof obtained from said metallo-organic solution, and
e) If necessary, repeating stages a)-d), optionally by changing the metallo-organic solution, until the desired final pattern or final multilayer structure is obtained.

2. Process according to claim 1, wherein the substrate is silicon.

3. Process according to claim 1, wherein the substrate is laminated mica.

4. Process according to claim 2, wherein the surface of the substrate is that of a monocrystal.

5. Process according to claim 1, wherein the substrate is a ceramic.

6. Process according to claim 5, wherein the substrate is a glass.

7. Process according to claim 1, wherein the substrate is a metal or a metal alloy.

8. Process according to claim 1, wherein the metallo-organic solution contains at least one organic salt of at least one metal that is selected from the group that is formed by: Cd, Ti, Al, Si, Fe, Co, Ni, Mn, Cr, Zn, Cu, Ca, Ba, Sr, Y, Zr, Sn, Ag, La, Hf, Ta, Pb, Bi, In, Ce, Pr, Nd, Sm, Eu, Gd, Yb, Er, Tb and U.

9. Process according to claim 8, wherein the metallo-organic salt or salts are selected from among the group that is formed by: the carboxylates, the propionates, the butyrates, the pentanoates, the metal methylbutyrates, or a mixture of the latter.

10. Process according to claim 9, wherein the metallo-organic solution also comprises at least one mineral salt of at least one noble metal that is selected from the group that is formed by Au, Ag and Pt, preferably AuCl₃, AgNO₃, or PtCl₅, or a mixture of the latter.

11. Process according to claim 1, wherein the energy beam is an electron beam.

12. Process according to claim 1, wherein the energy beam is an ion beam.

13. Process according to claim 1, wherein the energy density of the energy beam is between 100 and 100,000 A.s.m⁻².

14. Process according to claim 13, wherein the energy density of the energy beam is adequate for modifying, in the exposed zones, the chemical nature of the metal or metals contained in the metallo-organic solution.

15. Process according to claim 14, wherein the metallo-organic solution that contains at least Cd or Zn also contains a compound that can release sulfide ions at the time of the exposure of stage b) and/or during the heat treatment of stage d).

16. Device that is produced in multiple layers, wherein it comprises at least one structure or a pattern obtained by the implementation of the process according to claim 1.

17. (canceled)

18. (canceled)

19. Process according to claim 3, wherein the surface of the substrate is that of a monocrystal.
